(19) United States
(12) Patent Application Publication
(10) Pub. No.: US 2024/0271283 A1
(43) Pub. Date: Aug. 15, 2024

(54) REACTION TUBE, SEMICONDUCTOR MANUFACTURING APPARATUS THEREWITH, AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Jeonghyeon LEE, Suwon-si (KR); Sangyub IE, Suwon-si (KR)

(73) Assignee: SAMSUNG ELECTRONICS CO., LTD., Suwon-si (KR)

(21) Appl. No.: 18/229,839

(22) Filed: Aug. 3, 2023

(30) Foreign Application Priority Data
Feb. 9, 2023 (KR) 10-2023-0017510

(51) Int. Cl. C23C 16/455; H01L 21/31

(52) U.S. Cl. CPC C23C 16/45591; H01L 21/31; H01L 21/0214; H01L 21/02164; H01L 21/0217

(57) ABSTRACT

A semiconductor manufacturing apparatus may include a substrate boat configured to load a plurality of substrates; a process chamber configured to enclose the substrate boat; and a reaction tube between the substrate boat and the process chamber. The reaction tube may include a gas flowing part configured to allow for a flow of a process gas; a process part defining gas slits and an exhausting hole; and baffles on an inner side surface of the process part, excluding the exhausting hole.

### CROSS-REFERENCE TO RELATED APPLICATION

This U.S. non-provisional patent application claims priority under 35 U.S.C. § 119 to Korean Patent Application No. 10-2023-0017510, filed on Feb. 9, 2023, in the Korean Intellectual Property Office, the entire contents of which are hereby incorporated by reference.

### BACKGROUND

### 1. Field

Embodiments of the present disclosure relate to a reaction tube including baffles corresponding to substrates, a semiconductor manufacturing apparatus therewith, and a method of manufacturing a semiconductor device using the same.

### 2. Description of Related Art

Due to their small-sized, multifunctional, and/or low-cost characteristics, semiconductor devices are being esteemed as important elements in the electronic industry. With the advancement of the electronics industry, there is an increasing demand for a semiconductor device with a higher integration density. To increase the integration density of the semiconductor device, it is necessary to reduce linewidths of patterns constituting the semiconductor device. However, novel and expensive exposure technologies are needed to reduce the linewidths of the patterns, and thus, it becomes difficult to increase the integration density of the semiconductor device. Recently, a variety of new technologies are being studied to overcome the difficulty in increasing an integration density of a semiconductor memory device.

### SUMMARY

An embodiment of the present disclosure provides a reaction tube including a baffle, a semiconductor manufacturing apparatus including the same, and a method of manufacturing a semiconductor device using the same.

According to embodiments of the present disclosure, a semiconductor manufacturing apparatus may be provided and include: a substrate boat configured to load a plurality of substrates: a process chamber configured to enclose the substrate boat; and a reaction tube between the substrate boat and the process chamber, wherein the reaction tube includes: a gas flowing part configured to allow for a flow of a process gas: a process part defining gas slits and an exhausting hole; and baffles on an inner side surface of the process part, excluding the exhausting hole.

According to embodiments of the present disclosure, a reaction tube may be provided and include: a side portion, wherein a first side of the side portion defines gas slits that are spaced apart from each other in a vertical direction, and a second side of the side portion, opposite to the first side, defines an exhausting hole; an upper portion connected to the side portion: baffles that are on an inner side surface of the side portion, excluding the exhausting hole, and are spaced apart from each other in the vertical direction; and a gas flowing part adjacent to an outer side surface of the side portion, wherein upper surfaces of portions of the side portion between the gas slits is at a same level as an upper surface of a respective one of the baffles, and wherein the baffles have an arc shape when viewed in a plan view.

According to embodiments of the present disclosure, a method of manufacturing a semiconductor device may be provided and include: loading substrates on a substrate boat: placing the substrate boat in a reaction tube after loading the substrates; performing a semiconductor manufacturing process with respect to the substrates in the reaction tube; and unloading the substrates after performing the semiconductor manufacturing process, wherein the reaction tube includes an upper portion, a side portion, and baffles on an inner side surface of the side portion, and wherein the placing the substrate boat in the reaction tube includes placing an upper surface of each of the substrates at a same level as an upper surface of a respective one of the baffles.

### BRIEF DESCRIPTION OF DRAWINGS

FIG. 1 is a sectional view illustrating a semiconductor manufacturing apparatus according to an embodiment of the present disclosure.

FIG. 2 is an exploded perspective view illustrating a portion of a reaction tube according to an embodiment of the present disclosure.

FIG. 3 is a detailed view depicting an example structure of a baffle according to an embodiment of the present disclosure.

FIG. 4 is a detailed view depicting an example structure of a baffle according to an embodiment of the present disclosure.

FIG. 5 is a detailed view depicting an example structure of a baffle according to an embodiment of the present disclosure.

FIG. 6 is a plan view, which is taken at a level I-I′ of FIG. 1 to illustrate a reaction tube according to an embodiment of the present disclosure.

FIG. 7 is a flow chart illustrating a method of manufacturing a semiconductor device, according to an embodiment of the present disclosure.

FIG. 8 is a first sectional view illustrating a part of a method of manufacturing a semiconductor device, according to an embodiment of the present disclosure.

FIG. 9 is a second sectional view illustrating a part of the method of manufacturing the semiconductor device, according to an embodiment of the present disclosure.

FIG. 10 is an enlarged sectional view illustrating a portion of FIG. 10.

FIG. 11 is a third sectional view illustrating a part of the method of manufacturing the semiconductor device, according to an embodiment of the present disclosure.

### DETAILED DESCRIPTION

Non-limiting example embodiments of the present disclosures will now be described more fully with reference to the accompanying drawings, in which non-limiting example embodiments are shown.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

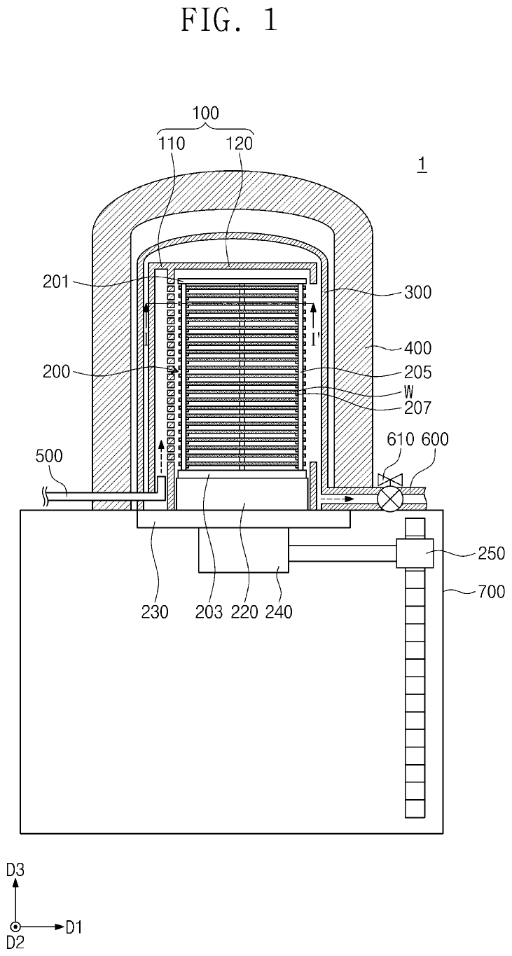

FIG. 1 is a sectional view illustrating a semiconductor manufacturing apparatus according to an embodiment of the present disclosure.

Referring to FIG. 1, a semiconductor manufacturing apparatus 1 may be provided. The semiconductor manufacturing apparatus 1 may be configured to perform a semiconductor manufacturing process. For example, the semiconductor manufacturing apparatus 1 may be configured to perform a deposition process on a plurality of substrates W. The semiconductor manufacturing apparatus 1 may be configured to supply process gases therein, and in this case, as a result of the reaction of the process gases, a thin film may be deposited on one or more of the substrates W. For example, the semiconductor manufacturing apparatus 1 may be a low pressure chemical vapor deposition (LPCVD) system which is operated under a low pressure condition of 1 Pa to 300 Pa. Each of the substrates W may be a semiconductor substrate, which is used to fabricate a semiconductor device, but embodiments of the present disclosure are not limited to this example.

The semiconductor manufacturing apparatus 1 may include a reaction tube 100, a substrate boat 200, an outer tube 300, a process chamber 400, a gas supplying part 500 (e.g., a gas supplier), a gas exhausting part 600 (e.g., a gas exhaust), and a housing 700.

The process chamber 400 may be configured to define an internal space, in which the reaction tube 100 and the outer tube 300 can be placed. The process chamber 400 may include a heating device. The heating device may be used to increase a temperature of the process chamber 400. Thus, a high-temperature semiconductor manufacturing process may be performed. In an embodiment, a plurality of heating devices may be provided to be spaced apart from each other in a height direction of the process chamber 400. In this case, the temperature of the process chamber 400 may be independently controlled along the vertical axis of the process chamber 400 (e.g., the height direction). The process chamber 400 may be formed of or include a material having a good heat-resistant property and a good corrosion-resistant property. For example, the process chamber 400 may be formed of or include yttrium oxide (Y₂O₃), but embodiments of the present disclosure are not limited to this example.

The reaction tube 100 and the outer tube 300 may be placed in an internal space of the process chamber 400. The outer tube 300 may be provided to enclose the reaction tube 100. That is, the outer tube 300 may be placed between the process chamber 400 and the reaction tube 100. Each of the reaction tube 100 and the outer tube 300 may have a cylindrical shape having a closed top, which allows for isolation from the outside, and an opened bottom, which allows for connection to the outside. The reaction tube 100 and the outer tube 300 may have a circular shape, when viewed in a plan view. The reaction tube 100 may be configured to have a process space, in which the substrates W can be loaded. A semiconductor manufacturing process on the substrates W may be performed in the process space of the reaction tube 100. The outer tube 300 may be connected to the gas supplying part 500 and the gas exhausting part 600.

The substrate boat 200 may be placed in the process space of the reaction tube 100 and on a supporting plate 220. The substrate boat 200 may include an upper plate 201, a lower plate 203, and connecting portions 205. The connecting portions 205 may be placed between the upper plate 201 and the lower plate 203. When viewed in a plan view, the connecting portions 205 may be placed along edges of the upper plate 201 and the lower plate 203 and may be spaced apart from each other. The connecting portions 205 may include substrate supporters 207, which are spaced apart from each other in a third direction D3. The substrates W may be placed on the substrate supporters 207, respectively. The substrate supporters 207 of each of the connecting portions 205 may be spaced apart from each other in the third direction D3, and thus, the substrates W may be spaced apart from each other in the third direction D3. In other words, the substrates W may be placed at different heights, which are spaced apart from each other in a vertical direction, when they are loaded in the substrate boat 200.

The substrate boat 200 may be placed on the supporting plate 220, and a sealing unit 230 (e.g., a seal) and a rotary unit 240 (e.g., a unit include a rotary actuator) may be placed below the supporting plate 220. The reaction tube 100 and the outer tube 300 may be hermetically sealed by the sealing unit 230. Thus, the reaction tube 100 and the outer tube 300 may be maintained in a low-pressure state, and the process gas may not be leaked to the outside. The sealing unit 230 may include an O-ring.

The rotary unit 240 may be placed below the sealing unit 230. The rotary unit 240 may be configured to rotate the substrate boat 200. The substrate boat 200 may be rotated in a clockwise or counterclockwise direction. That is, the substrates W may be rotated in the clockwise or counterclockwise direction, during the semiconductor manufacturing process. Thus, a reaction gas may be uniformly supplied onto one or more of the substrates W, and this may make it possible to improve process uniformity of the semiconductor manufacturing process performed on the one or more of the substrates W.

An elevator 250 may be placed in the housing 700 and may be connected to the rotary unit 240. The elevator 250 may be movable in the housing 700 in the third direction D3. Since the substrate boat 200 is connected to the rotary unit 240, the substrate boat 200 may be moved in the third direction D3 by the elevator 250. That is, the substrate boat 200 may be loaded in or unloaded from the process chamber 400 and the reaction tube 100 by the elevator 250.

The gas supplying part 500 may be connected to the process chamber 400. In detail, the gas supplying part 500 may be connected to the reaction tube 100 placed in the process chamber 400. The gas supplying part 500 may be configured to supply the process gas from a gas supplying device to the reaction tube 100. For example, the process gas may include at least one from among dichlorosilane (SiH₂Cl₂), hexachlorodisilane (HCDS), ammonia (NH₃), oxygen (O₂), argon (Ar), or nitrogen (N2), but embodiments of the present disclosure are not limited to these examples.

In an embodiment, the gas supplying part 500 may be provided in plural. For example, the gas supplying part 500 may include a first gas supplying part and a second gas supplying part. In this case, the process gases of different kinds may be supplied at the same time.

The gas exhausting part 600 may be configured to exhaust the process gas from the process chamber 400 to the outside. The gas exhausting part 600 may be connected to a vacuum pump. In other words, the gas exhausting part 600 may connect the outer tube 300 to the vacuum pump. The vacuum pump may be used to lower an internal pressure of the process chamber 400. A gate valve 610 may be placed on the gas exhausting part 600. The gate valve 610 may be used to control the pressure of the process chamber 400.

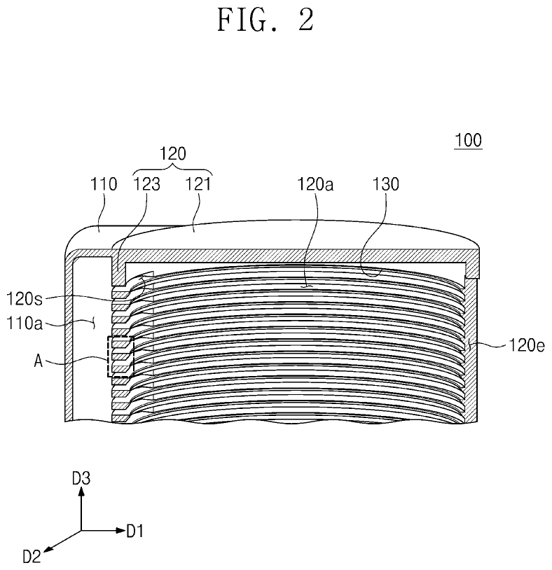

FIG. 2 is an exploded perspective view illustrating a portion of a reaction tube according to an embodiment of the present disclosure.

Referring to FIG. 2, the reaction tube 100 may include a gas flowing part 110, a process part 120, and baffles 130. The process part 120 may be composed of an upper portion 121 and a side portion 123. The gas flowing part 110 may be placed on a side surface of the process part 120. The gas flowing part 110 and the process part 120 may be in contact with each other.

The gas flowing part 110 may have a shape elongated in the third direction D3. The gas flowing part 110 may be configured to define a gas flowing passageway 110a. The gas flowing part 110 may be connected to the gas supplying part 500 of FIG. 1. The process gas, which is supplied from the gas supplying part 500, may flow through the gas flowing passageway 110a of the gas flowing part 110 in the third direction D3. That is, the process gas may be supplied to the reaction tube 100, from the bottom to the top, through the gas flowing passageway 110a. Accordingly, the process gas may be supplied to the entire space of the reaction tube 100, regardless of the height of the reaction tube 100.

A process space 120a may be defined by the upper portion 121 and the side portion 123 of the process part 120. An upper portion of the side portion 123 of the process part 120 may be connected to the upper portion 121 of the process part 120. The upper portion 121 of the process part 120 may not have a hole or a slit. That is, the process space 120a of the process part 120 may not be connected to an outer space through the upper portion 121. In other words, the process part 120 may be shaped like a cylinder having a closed top and an opened bottom. The upper portion 121 and the side portion 123 of the process part 120 may be provided in the form of a single object (e.g., the upper portion 121 and the side portion 123 may be integrally formed with respect to each other), but embodiments of the present disclosure are not limited to this example.

Gas slits 120s may be provided to penetrate the side portion 123 of the process part 120 in a first direction D1. In detail, the gas slits 120s may be formed in a portion of the process part 120 that is in contact with the gas flowing part 110. Each of the gas slits 120s may have a shape extending in a second direction D2. The gas slits 120s may be spaced apart from each other in the third direction D3. The gas flowing passageway 110a of the gas flowing part 110 and the process space 120a of the process part 120 may be connected to each other through the gas slits 120s. In other words, the process gas may be moved in the third direction D3 through the gas flowing passageway 110a and may be supplied into the process space 120a, in the first direction D1, through the gas slits 120s.

An exhausting hole 120e may be provided to penetrate the side portion 123 of the process part 120 in the first direction D1. The exhausting hole 120e may be provided at a side of the side portion 123 that is opposite to another side of the side portion 123 that includes the gas slits 120s. In other words, the exhausting hole 120e may be provided to face the gas slits 120s. The process gas in the process space 120a may be exhausted to the outside through the exhausting hole 120e. The exhausting hole 120e may have a shape elongated in the third direction D3.

The baffles 130 may be provided on an inner side surface of the side portion 123, excluding a region corresponding to the exhausting hole 120e. In other words, the baffles 130 may have an arc shape. Each of the baffles 130 may be parallel to a respective plane defined by the first direction D1 and the second direction D2. Each of the baffles 130 may have a protruding shape that is extended from the inner side surface of the side portion 123 toward a center of the process part 120. The baffles 130 may be spaced apart from each other in the third direction D3.

One of the baffles 130 may correspond to one of the gas slits 120s. One of the baffles 130 may correspond to one of the substrates W of FIG. 1. In other words, the numbers of the gas slits 120s and the baffles 130 may be determined by the number of the substrates W. The process gas may flow through a plurality of structures, each of which is composed of one of the gas slits 120s, one of the baffles 130, and one of the substrates W.

According to an embodiment of the present disclosure, the gas slits 120s and the exhausting hole 120e of the reaction tube 100 may be provided in the side portion 123 of the process part 120 to face each other. In addition, since the reaction tube 100 includes the upper portion 121, the process gas may not flow in an upward direction. That is, the process gas in the process space 120a of the reaction tube 100 may be restricted to flow through a horizontal path.

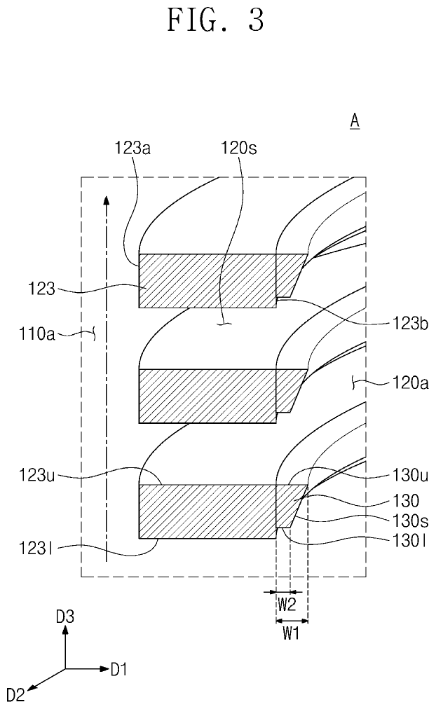

FIGS. 3 to 5 are detailed views, of a portion A of FIG. 2, that depict non-limiting example structures of a baffle according to embodiments of the present disclosure.

In the following description, an element previously described with reference to FIG. 2 may be identified by the same reference number without repeating an overlapping description thereof, for convenience in description.

Referring to FIG. 3, the side portion 123 between the gas slits 120s may have an upper surface 123u, a lower surface 1231, an outer side surface 123a, and an inner side surface 123b. The outer side surface 123a of the side portion 123 between the gas slits 120s may be adjacent to the gas flowing passageway 110a. The inner side surface 123b of the side portion 123 between the gas slits 120s may be adjacent to the process space 120a. The process gas may be moved to the upper surface 123u and the lower surface 1231 of the side portion 123 between the gas slits 120s.

Each of the baffles 130 may be placed on the inner side surface 123b of the side portion 123 between the gas slits 120s and may be in contact with the side portion 123 between the gas slits 120s. The baffles 130 and the side portion 123 may be provided in the form of a single object, but embodiments of the present disclosure are not limited to this example.

Each of the baffles 130 may have an upper surface 130u, a lower surface 1301, and a side surface 130s. The upper surface 130u of the baffle 130 may be located at the same level as the upper surface 123u of the side portion 123 between the gas slits 120s. The lower surface 1301 of the baffle 130 may not be coplanar with the lower surface 1231 of the side portion 123 between the gas slits 120s. In other words, a thickness of the baffles 130 in the third direction D3 may be smaller than a thickness of the side portion 123 between the gas slits 120s in the third direction D3. The side surfaces 130s of the baffles 130 may be placed between the upper surface 130u and the lower surface 1301 of the baffles 130 and may be adjacent to the process space 120a. The side surfaces 130s of the baffles 130 may not extend parallel to the third direction D3. That is, the side surfaces 130s of the baffles 130 may be a surface that is inclined at an angle with respect to the third direction D3. That is, each of the baffles 130 may have a tetragonal or rectangular section.

The upper surface 130u of the baffle 130 may have a first width W1 in the first direction D1. The lower surface 1301 of the baffle 130 may have a second width W2 in the first direction D1. The first width W1 may be larger than the second width W2. For example, each of the first width W1 and the second width W2 may range from about 1 mm to about 3 mm.

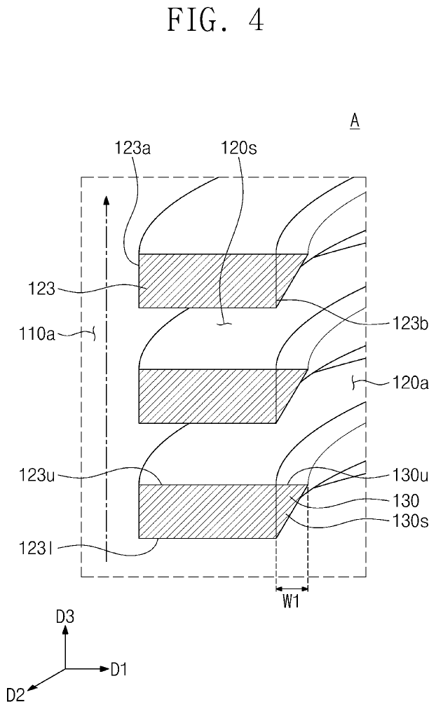

Referring to FIG. 4, the baffles 130 may be placed on the inner side surface 123b of the side portion 123 between the gas slits 120s. The upper surface 130u of each of the baffles 130 may be coplanar with the upper surface 123u of the side portion 123 between the gas slits 120s. The upper surface 130u of the baffle 130 may have the first width W1 in the first direction D1.

Unlike the structure illustrated in FIG. 3, the baffles 130 may not have the lower surface 1301. In addition, when measured in the third direction D3, a thickness of each of the baffles 130 may be substantially equal to a thickness of the side portion 123 between the gas slits 120s. That is, each of the baffles 130 may have a triangle section.

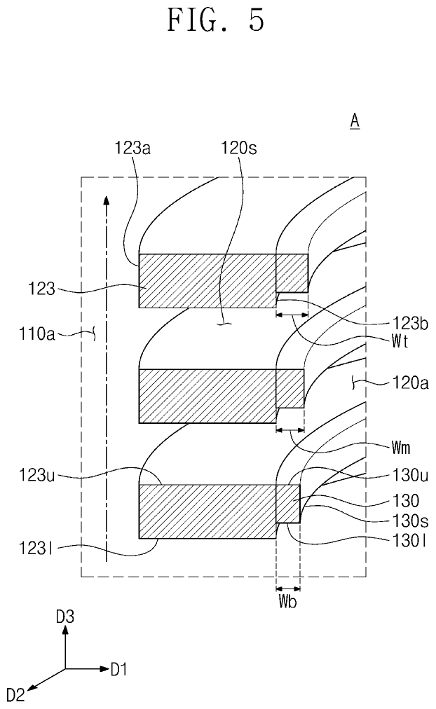

Referring to FIG. 5, each of the baffles 130 may be placed on the inner side surface 123b of the side portion 123 between the gas slits 120s. The upper surface 130u of each of the baffles 130 may be coplanar with the upper surface 123u of the side portion 123 between the gas slits 120s. The upper surface 130u and the lower surface 1301 of each of the baffles 130 may have the same width, when measured in the first direction D1. That is, the side surfaces 130s of the baffles 130 may be parallel to the third direction D3, and each of the baffles 130 may have a rectangular section.

For example, the baffles 130 may have widths Wt, Wm, and Wb, which are different from each other, in a horizontal direction. The width Wt of an upper one of the baffles 130 in the first direction D1 may be larger than the width Wm of an intermediate one of the baffles 130 in the first direction D1. The width Wm of the intermediate one of the baffles 130 in the first direction D1 may be larger than the width Wb of a lower one of the baffles 130 in the first direction D1. In other words, as a height in the third direction D3 increases, the widths Wt, Wm, and Wb of the baffles 130 in a horizontal direction may increase. However, embodiments of the present disclosure are not limited to this example. That is, as the height in the third direction D3 increases, the widths Wt, Wm, and Wb of the baffles 130 in the horizontal direction may decrease. In addition, the width Wm of the intermediate one of the baffles 130 may be the largest width in the first direction D1. Thus, it may be possible to adjust an amount of the process gas supplied onto the substrate, in accordance with the height. Accordingly, it may be possible to reduce a variation in process characteristics between the substrates.

Referring back to FIGS. 3 to 5, the baffles 130 may be provided in various shapes. The baffles 130 may be provided to have a protruding shape that is extended from the inner side surface 123b of the side portion 123 toward the process space 120a. The gas exhausting part 600 of the semiconductor manufacturing apparatus 1 of FIG. 1 may be placed under a bottom end of the reaction tube 100. Thus, the process gas in the process space 120a may flow in a downward direction.

According to an embodiment of the present disclosure, the upper surface 130u of each of the baffles 130 may be placed at the same level as the upper surface 123u of the side portion 123 between the gas slits 120s. Furthermore, the baffles 130 may not be overlapped with the gas slits 120s in a horizontal direction. Accordingly, the process gas passing through the gas slits 120s may be supplied into the process space 120a along the upper surfaces 130u of the baffles 130. That is, the baffles 130 may prevent the process gas, which passes through the gas slits 120s, from being moved downward by the gas exhausting part 600 of the semiconductor manufacturing apparatus 1. In other words, the baffles 130 may be used as a component for guiding the process gas, which passes through the gas slits 120s, to move in a horizontal direction. Accordingly, the process gas may be supplied to a region on the substrate without forming a downward flow, in a semiconductor manufacturing process to be described.

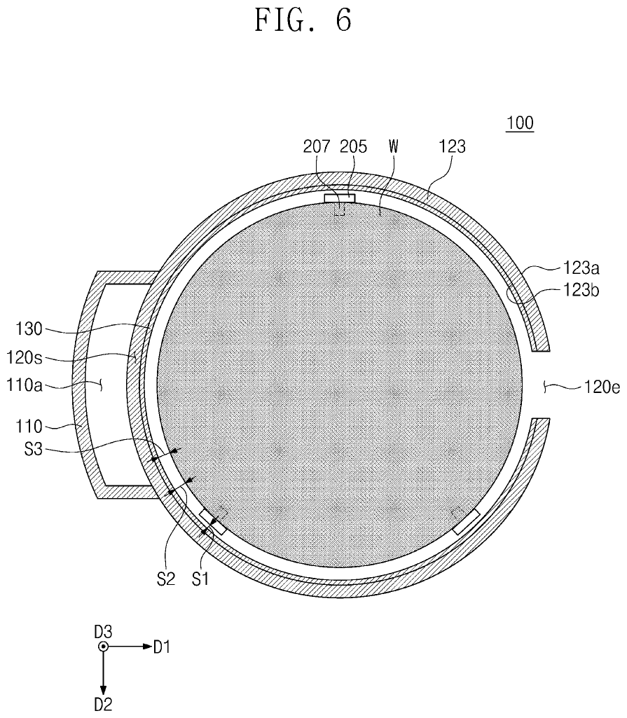

FIG. 6 is a plan view, which is taken at a level I-I′ of FIG. 1 to illustrate a reaction tube according to an embodiment of the present disclosure.

In the following description, an element previously described with reference to FIG. 2 may be identified by the same reference number without repeating an overlapping description thereof, for convenience in description.

Referring to FIG. 6, the substrate W may be provided in the reaction tube 100. The substrate W may be placed on the substrate supporters 207 of the connecting portions 205. When viewed in a plan view, the connecting portions 205 may be spaced apart from each other and may be placed at three vertices of a triangle. For example, an angle between the connecting portions 205 may be 120°, but embodiments of the present disclosure are not limited to this example.

The baffle 130 may be placed on the inner side surface 123b of the side portion 123. The baffle 130 may not be provided on the exhausting hole 120e. The baffle 130 may have an arc shape, when viewed in a plan view. That is, since the baffle 130 is not provided on the exhausting hole 120e, the process gas may be effectively moved to the exhausting hole 120e.

A distance between the connecting portion 205 and the baffle 130 may be a first distance S1. A distance between an edge portion of the substrate W and the baffle 130 may be a second distance S2. A distance between the edge portion of the substrate W and the inner side surface 123b of the side portion 123 may be a third distance S3. The first distance S1 may be smaller than the second distance S2. The second distance S2 may be smaller than the third distance S3. That is, the first distance S1 may be the smallest, and the third distance S3 may be the largest. For example, the first distance S1 may range from about 1 mm to 2 mm. The second distance S2 may range from about 8 mm to 12 mm. The third distance S3 may range from about 13 mm to 15 mm.

In other words, since the downward flow of the process gas is prevented by the baffle 130, the process gas may be moved on the baffle 130 only in a horizontal direction. That is, the process gas may be moved in only the horizontal direction until it reaches a sufficient proximity to the substrate W, which may enable an increase in an amount of the process gas supplied onto the substrate W. As a result, it may be possible to form a layer with a sufficiently large thickness, even when an amount of the process gas is reduced, or it may be possible to decrease the process time for the semiconductor manufacturing process.

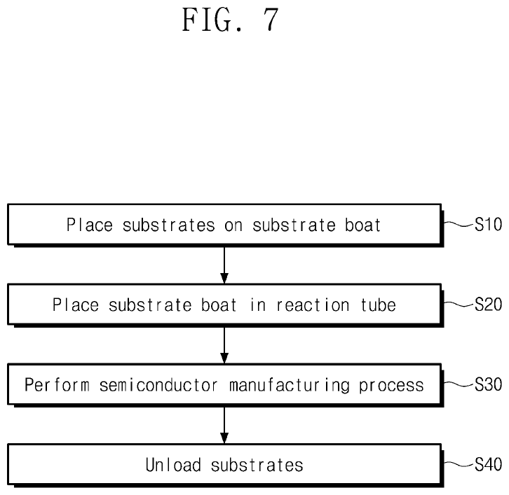

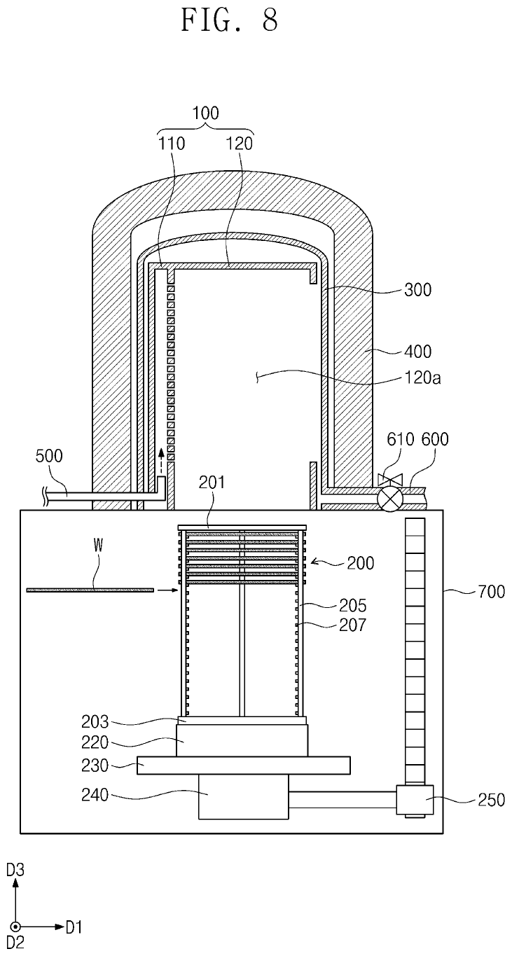

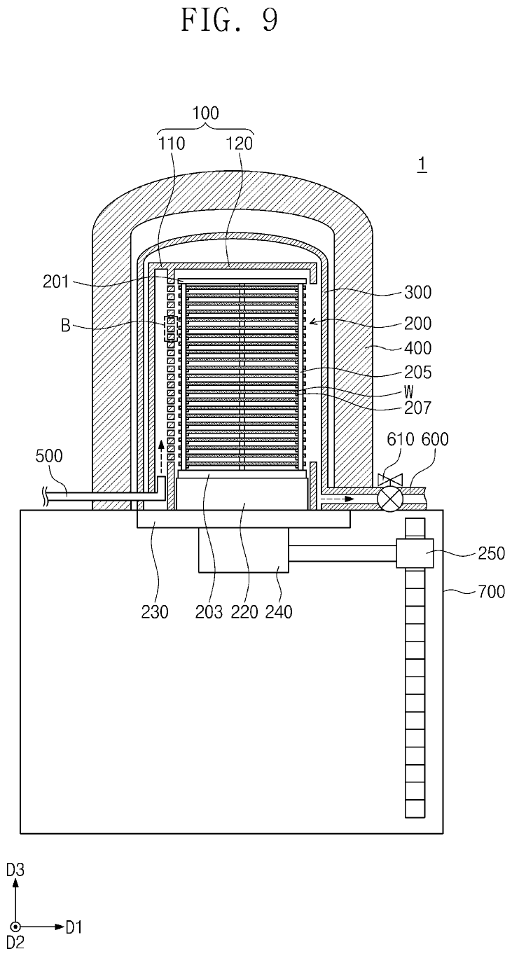

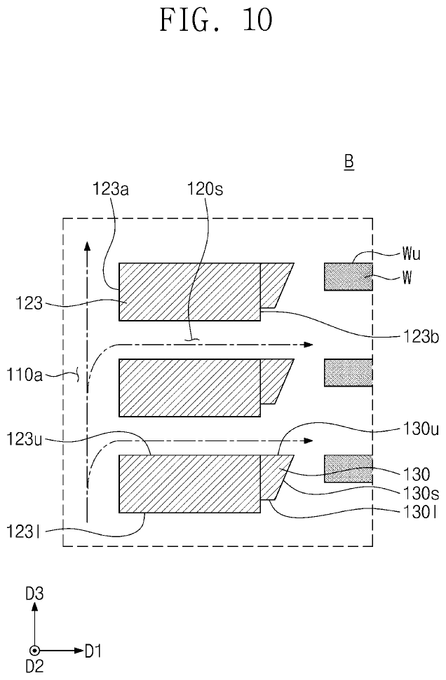

FIG. 7 is a flow chart illustrating a method of manufacturing a semiconductor device, according to an embodiment of the present disclosure. FIGS. 8, 9, and 11 are sectional views illustrating a method of manufacturing a semiconductor device, according to an embodiment of the present disclosure, and FIG. 10 is an enlarged sectional view illustrating a portion ‘B’ of FIG. 9.

Referring to FIGS. 7 and 8, a plurality of substrates W may be placed on a substrate boat 200 (step S10), and in an embodiment, this step may include placing the substrates W at different heights.

The substrate boat 200 may be downwardly moved in the third direction D3 by the elevator 250 and may be placed in the housing 700. A transfer device may be used to place the substrates W on the substrate supporters 207 of the substrate boat 200. Since the substrate supporters 207 are spaced apart from each other in the third direction D3, the substrates W may also be placed at heights that are spaced apart from each other in the third direction D3. That is, the substrates W may be placed at different heights, in the substrate boat 200.

Referring to FIGS. 7, 9, and 10, the substrate boat 200 may be loaded in the reaction tube 100 (step S20), and in an embodiment, this step may include elevating the substrate boat 200 in the third direction D3 and the placing the upper surface Wu of each of the substrates W at the same level as an upper surface 130u of a corresponding one of the baffles 130. The substrate boat 200 may be elevated in the third direction D3 by the elevator 250. Accordingly, the substrate boat 200 may be placed in the process space 120a of the reaction tube 100. The substrate boat 200 may be elevated in the third direction D3 until the upper surface Wu of the substrates W is located at the same level as the upper surface 130u of a corresponding one of the baffles 130.

Thereafter, a semiconductor manufacturing process may be performed (step S30). The semiconductor manufacturing process (step S30) may include supplying the process gas using the gas supplying part 500, horizontally flowing the process gas toward a region on the upper surface Wu of the substrates W, and forming a layer on the substrates W.

The process gas may be supplied into the gas flowing part 110 of the reaction tube 100 through the gas supplying part 500. In the gas flowing passageway 110a of the gas flowing part 110, the process gas may flow in the third direction D3. The process gas may flow in the first direction D1 through the gas slits 120s. In other words, a horizontal flow of the process gas may be formed through the gas slits 120s.

The upper surface 123u of the side portion 123 between the gas slits 120s may be located at the same level as the upper surface 130u of each of the baffles 130, and the upper surface 130u of each of the baffles 130 may be located at the same level as the upper surface Wu of the substrate W. Thus, the process gas may pass through a region on the upper surface 123u of the side portion 123 and the upper surfaces 130u of the baffles 130 and then may be easily supplied to a region on the upper surface Wu of the substrates W. Here, since the baffles 130 prevents the process gas from flowing through a gap between the side portion 123 of the reaction tube 100 and the substrate W, an amount of the process gas supplied onto the substrates W may be increased. This may facilitate a process of forming a layer on the substrates W.

In an embodiment, the semiconductor manufacturing process may be a process of depositing a uniformly thin film, which is used as a part of a three-dimensional semiconductor memory device, on a structure having a high aspect ratio, or etching such a thin film. As an example, the semiconductor manufacturing process may be a process of depositing an insulating material on a substrate. The insulating material may include at least one from among silicon oxide, silicon nitride, and silicon oxynitride.

The semiconductor manufacturing process (step S30) may further include rotating the substrate boat 200. The substrate boat 200 may be rotated in a clockwise or counterclockwise direction by the rotary unit 240. Due to the rotation of the substrate boat 200, the process gas may be supplied onto the substrates W in an isotropic and homogeneous manner. Thus, in the semiconductor manufacturing process (step S30), it may be possible to reduce a variation of process characteristics in each substrate W.

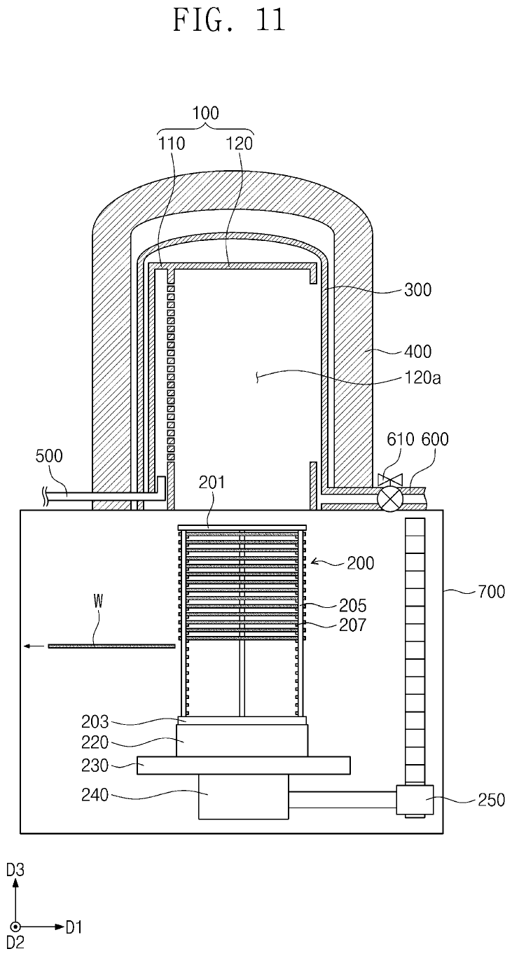

Referring to FIGS. 7 and 11, the substrates W may be unloaded (step S40), and in an embodiment, this step may include lowering the substrate boat 200 in the third direction D3 and unloading the substrates W from the substrate boat 200.

The substrate boat 200 may be lowered in the third direction D3 by the elevator 250 such that it is placed within the housing 700. Thereafter, the substrates W may be unloaded from the substrate boat 200 by a transfer device. That is, the unloading of the substrate (step S40) may be accomplished by performing the steps S10 and S20 in reverse order. More particularly, the steps may include removing the substrate boat 200 from the reaction tube 100 and the removing the substrates W from the substrate boat 200.

In a reaction tube according to an embodiment of the present disclosure and a semiconductor manufacturing apparatus including the same, a baffle may be provided on an inner side surface of a reaction tube adjacent to a gas slit. The baffle may be configured to impede a process gas, which passes through the gas slit, from flowing in a downward direction, and consequently, the process gas may be supplied to a region on a substrate in a horizontal direction. That is, the baffle of the reaction tube may be used to control the flow of the process gas or to allow for the horizontal flow of the process gas. This may make it possible to increase an amount of the process gas supplied to the region on the substrate. As a result, it may be possible to form a layer with a sufficiently large thickness, even when an amount of the process gas is reduced. Additionally, it may allow for a reduction in the process time required for the semiconductor manufacturing process.

While non-limiting example embodiments of the present disclosure have been particularly shown and described, it will be understood by one of ordinary skill in the art that variations in form and detail may be made thereof without departing from the spirit and scope of the present disclosure.

What is claimed is:

1. A semiconductor manufacturing apparatus, comprising:
a substrate boat configured to load a plurality of substrates;
a process chamber configured to enclose the substrate boat; and
a reaction tube between the substrate boat and the process chamber,
wherein the reaction tube comprises:
a gas flowing part configured to allow for a flow of a process gas;
a process part defining gas slits and an exhausting hole; and
baffles on an inner side surface of the process part, excluding the exhausting hole.

2. The semiconductor manufacturing apparatus of claim 1, wherein the baffles have an arc shape when viewed in a plan view.

3. The semiconductor manufacturing apparatus of claim 1, wherein the baffles are spaced apart from each other in a vertical direction.

4. The semiconductor manufacturing apparatus of claim 1, wherein the gas slits are in the process part that is adjacent to the gas flowing part, and
the exhausting hole is in the process part that is opposite to the gas slits.

5. The semiconductor manufacturing apparatus of claim 1, wherein the gas slits extend in a horizontal direction and are spaced apart from each other in a vertical direction.

6. The semiconductor manufacturing apparatus of claim 1, wherein the baffles are not overlapped with the gas slits in a horizontal direction.

7. The semiconductor manufacturing apparatus of claim 1, wherein the baffles have different widths from each other in a horizontal direction.

8. The semiconductor manufacturing apparatus of claim 1, wherein the process part comprises an upper portion and a side portion that are coupled to each other, and
the gas slits and the exhausting hole are defined in the side portion.

9. The semiconductor manufacturing apparatus of claim 8, wherein an upper surface of each of the baffles is coplanar with an upper surface of a respective portion of the side portion between the gas slits.

10. The semiconductor manufacturing apparatus of claim 8, wherein a distance in a horizontal direction between an innermost part of the baffles and a center of a process space of the process part is smaller than a distance in the horizontal direction between an innermost part of the side portion and the center of the process part.

11. The semiconductor manufacturing apparatus of claim 8, wherein the baffles and the process part are integrally formed.

12. The semiconductor manufacturing apparatus of claim 1, further comprising an outer tube between the reaction tube and the process chamber.

13. A reaction tube, comprising:
a side portion defines gas slits that are spaced apart from each other in a vertical direction, and an exhausting hole, that is opposite to the gas slits;
an upper portion connected to the side portion;
baffles that are on an inner side surface of the side portion, excluding on the exhausting hole, and are spaced apart from each other in the vertical direction; and
a gas flowing part adjacent to the gas slits of the side portion,
wherein upper surfaces of portions of the side portion between the gas slits is at a same level as an upper surface of a respective one of the baffles, and
wherein the baffles have an arc shape when viewed in a plan view.

14. The reaction tube of claim 13, wherein the gas flowing part defines a gas flowing passageway,
the upper portion and the side portion define a process space, and
the gas flowing passageway is connected to the process space through the gas slits.

15. The reaction tube of claim 13, wherein each of the gas slits extends in a horizontal direction, and
the exhausting hole extends in the vertical direction.

16. The reaction tube of claim 13, wherein a width of the upper surface of each of the baffles is larger than a width of a lower surface of each of the baffles.

17. A method of manufacturing a semiconductor device, the method comprising:
loading substrates on a substrate boat;
placing the substrate boat in a reaction tube after loading the substrates;
performing a semiconductor manufacturing process with respect to the substrates in the reaction tube; and
unloading the substrates after performing the semiconductor manufacturing process,
wherein the reaction tube includes an upper portion, a side portion, and baffles on an inner side surface of the side portion, and
wherein the placing the substrate boat in the reaction tube comprises placing an upper surface of each of the substrates at a same level as an upper surface of a respective one of the baffles.

18. The method of claim 17, wherein the performing the semiconductor manufacturing process comprises supplying, in a horizontal direction, a process gas to a region on the upper surface of each of the substrates.

19. The method of claim 17, wherein the performing the semiconductor manufacturing process comprises rotating the substrate boat in a clockwise or counterclockwise direction.

20. The method of claim 17, wherein the performing the semiconductor manufacturing process comprises forming at least one from among a silicon oxide layer, a silicon nitride layer, and a silicon oxynitride layer on the substrates.
